(19) United States
(12) Patent Application Publication
(10) Pub. No.: US 2023/0402505 A1
(43) Pub. Date: Dec. 14, 2023

(54) HIGH DENSITY 3D TRANSPORT DEVICE NANO SHEET

(71) Applicant: Tokyo Electron Limited, Tokyo (JP)

(72) Inventors: Mark I. Gardner, Albany, NY (US); H. Jim Fulford, Albany, NY (US)

(73) Assignee: Tokyo Electron Limited, Tokyo (JP)

(21) Appl. No.: 17/836,904

(22) Filed: Jun. 9, 2022

(51) Int. Cl. H01L 29/06; H01L 29/423; H01L 29/786; H01L 29/417; H01L 29/66; H01L 27/06; H01L 27/088

(52) U.S. Cl. CPC H01L 29/0665; H01L 29/42392; H01L 29/78618; H01L 29/78696; H01L 29/41775; H01L 29/66742; H01L 27/0688; H01L 27/0886

(57) ABSTRACT

A semiconductor device may include a transistor structure. The transistor structure can include a first source/drain structure. The transistor structure can include a first channel structure disposed above the first source/drain structure. The transistor structure can include a second source/drain structure disposed above the first channel structure. A sidewall of a first portion of the first source/drain structure, a sidewall of the first channel structure, and a sidewall of the second source/drain structure can be vertically aligned with one another. The transistor structure can include a first metal electrode disposed around the sidewall of the first channel structure and the sidewall of the second source/drain structure.

### TECHNICAL FIELD

The present disclosure relates generally to the field of manufacturing transistors.

### BACKGROUND

In the manufacture of semiconductor devices (especially on the microscopic scale), various fabrication processes are executed, such as film-forming depositions, etch mask creation, patterning, material etching and removal, and doping treatments. These processes are performed repeatedly to form desired semiconductor device elements on a substrate. In certain systems, microfabrication techniques manufacture transistors in one plane, while wiring or metallization is formed above the active device plane. Such devices are accordingly characterized as two-dimensional (2D) circuits, manufactured using 2D fabrication techniques.

### SUMMARY

Three-dimensional (3D) integration, e.g., a stacking (or vertical arrangement) of multiple semiconductor devices (e.g., transistor structures), can overcome scaling limitations experienced in planar devices (e.g., two-dimensional (2D) planar device) by increasing transistor density in volume rather than area. Although device stacking has been successfully demonstrated and implemented by the flash memory industry with the adoption of 3D NAND, applications to enhance gate-pitch-scaling limits, stack 3D transistors, and resolve problems faced by lateral transport devices are substantially more difficult. 3D integration for logic chips (e.g., CPU (central processing unit), GPU (graphics processing unit), FPGA (field programmable gate array, SoC (system on a chip)) is being pursued.

Techniques herein include methods and devices for 3D manufacturing of semiconductor devices. Techniques may include using a high-density 3D transport transistor vertical field-effect transistor (VFET) to overcome the gate-itch-scaling limits faced by lateral transport devices. A gate-all-around (GAA) transistor (e.g., sometimes referred to generally as a vertical transistor) may include a formation of gate electrode (e.g., metal electrode) disposed around the sidewall of the channel structure and at least one source/drain (S/D) structure of the vertical transistor. The S/D structures (e.g., first S/D structure and second S/D structure, etc.) and the channel structure may be disposed vertically and aligned with one another.

Such techniques discussed herein overcome the gate-itch-scaling limits faced by lateral transport devices and improve electrostatics and dynamic performance (e.g., at sub-45 nm) of the transistor devices. Techniques herein may use differential growth S/D structures and the channel structure to enable high-density gate electrode formation. Further, the techniques described herein may use wafer bonding to enhance the augmentation of the 3D stack height for stacking multiple transistor devices. By using the transport nanosheet, the electrical results show improved subthreshold slope (SS), drain induced barrier lowering (DIBL), and enhanced device operation over a FinFET achieved with aggressively scaled gate pitches. Further, transport nanosheets can avoid lateral FET scaling limits, thereby delivering an enhanced operating voltage range and providing improved drive strength and flexibility relative to FinFETs and nanowires. The intrinsic benefit of the transport nanosheet has significant circuit capacitance reduction (˜50%) over a scaled lateral FET. The techniques further utilized herein can scale beyond the limits of lateral-transport FET nanosheet architectures by using vertical-transport nanosheets. Further, embodiments herein can achieve improvements to the ring oscillator (RO) performance using the vertical transistor device architecture with reduced circuit capacitance. The embodiments will provide several process flows to provide a vertical transistor.

One aspect of the present disclosure may be directed to a semiconductor device. The semiconductor device may include a first transistor structure. The first transistor structure can include a first source/drain structure. The first transistor structure can include a first channel structure disposed above the first source/drain structure. The first transistor structure can include a second source/drain structure disposed above the first channel structure. A sidewall of a first portion of the first source/drain structure, a sidewall of the first channel structure, and a sidewall of the second source/drain structure can be vertically aligned with one another. The first transistor structure can include a first metal electrode disposed around the sidewall of the first channel structure and the sidewall of the second source/drain structure.

The semiconductor device can include a second transistor structure laterally disposed next to the first transistor structure. The second transistor structure can include a third source/drain structure. The second transistor structure can include a second channel structure disposed above the third source/drain structure. The second transistor structure can include a fourth source/drain structure disposed above the second channel structure. A sidewall of a first portion of the third source/drain structure, a sidewall of the second channel structure, and a sidewall of the fourth source/drain structure can be vertically aligned with one another. The second transistor structure can include a second metal electrode disposed around the sidewall of the second channel structure and the sidewall of the fourth source/drain structure.

The first source/drain structure and the second source/drain structure may have a first conductive type, while the first channel structure can include a second, opposite conductive type. The third source/drain structure and the fourth source/drain structure can have the second conductive type, while the second channel structure has the first conductive type. The first source/drain structure and the second source/drain structure may have a higher doping concentration than the first channel structure. The third source/drain structure and the fourth source/drain structure may have a higher doping concentration than the second channel structure.

The first transistor structure can include a dielectric layer at least disposed around the sidewall of the second source/drain structure. The first transistor structure can include a gate dielectric layer disposed around the sidewall of the first channel structure and a sidewall of the dielectric layer. The first metal electrode may be disposed around a sidewall of the gate dielectric layer. The gate dielectric layer may have a high-k dielectric material.

The first source/drain structure can include a second portion disposed below the first portion and laterally extending beyond the sidewall of the first portion.

The semiconductor device can include a third transistor structure vertically disposed with respect to the first transistor structure. The third transistor structure can include a fifth source/drain structure. The third transistor structure can a third channel structure disposed above the fifth source/drain structure. The third transistor structure can a sixth source/drain structure disposed above the third channel structure. A sidewall of a first portion of the fifth source/drain structure, a sidewall of the third channel structure, and a sidewall of the sixth source/drain structure can be vertically aligned with one another. The third transistor structure can include a third metal electrode disposed around the sidewall of the third channel structure and the sidewall of the sixth source/drain structure.

The first source/drain structure, the second source/drain structure, the fifth source/drain structure, and the sixth source/drain structure may have a first conductive type. The first channel structure and third channel structure may have a second, opposite conductive type.

Another aspect of the present disclosure may be directed to a semiconductor device. The semiconductor device can include a first transistor structure. The first transistor structure can include a first source/drain structure having a first portion and a second portion, wherein the first portion is below the second portion and laterally extending beyond a sidewall of the second portion. The first transistor structure can include a first channel structure disposed above the first source/drain structure and having a sidewall vertically aligned with the sidewall of the second portion of the first source/drain structure. The first transistor structure can include a second source/drain structure disposed above the first channel structure and having a sidewall vertically aligned with the sidewall of the first channel structure. The first transistor structure can include a first dielectric layer disposed around the sidewall of the second source/drain structure. The first transistor structure can include a first gate dielectric layer disposed around the sidewall of the first channel structure and a sidewall of the first dielectric layer. The first transistor structure can include a first metal electrode disposed around a sidewall of the first gate dielectric layer.

The semiconductor device can include a second transistor structure. The second transistor structure can include a third source/drain structure having a first portion and a second portion, wherein the first portion is below the second portion and laterally extending beyond a sidewall of the second portion. The second transistor structure can include a second channel structure disposed above the third source/drain structure and having a sidewall vertically aligned with the sidewall of the second portion of the third source/drain structure. The second transistor structure can include a fourth source/drain structure disposed above the second channel structure and having a sidewall vertically aligned with the sidewall of the second channel structure. The second transistor structure can include a second dielectric layer disposed around the sidewall of the fourth source/drain structure. The second transistor structure can include a second gate dielectric layer disposed around the sidewall of the second channel structure and a sidewall of the second dielectric layer. The second transistor structure can include a second metal electrode disposed around a sidewall of the second gate dielectric layer.

The second transistor structure can be laterally disposed next to the first transistor structure. The first transistor structure and second transistor structure may have opposite conductive types.

The second transistor structure may be vertically disposed with respect to the first transistor structure. The first transistor structure and second transistor structure may have a same conductive type.

Yet another aspect of the present disclosure may be directed to a method for manufacturing semiconductor devices. The method may include: forming a first stack including a first semiconductor layer having a first conductive type, a second semiconductor layer having a second conductive type, and a third semiconductor layer having the first conductive type; growing a first dielectric layer along the first stack, with a first portion having a first thickness grown on the first and third semiconductor layers and a second portion having a second thickness grown on the second semiconductor layer, wherein the first thickness is greater than the second thickness; forming a first gate dielectric layer around a sidewall of the second semiconductor layer and a sidewall of the dielectric layer; and forming a first gate electrode around the gate dielectric layer

Concurrently with the step of forming a first stack, the method further comprises: forming a second stack laterally disposed next to the first stack and including a fourth semiconductor layer having the second conductive type, a fifth semiconductor layer having the first conductive type, and a sixth semiconductor layer having the second conductive type.

Concurrently with the step of forming a first stack, the method further comprises: forming a second stack laterally disposed next to the first stack and including a fourth semiconductor layer having the second conductive type, a fifth semiconductor layer having the first conductive type, and a sixth semiconductor layer having the second conductive type.

Concurrently with the step of forming a first gate dielectric layer, the method further comprises: growing a second dielectric layer along the second stack, with a first portion having the first thickness grown on the fourth and sixth semiconductor layers and a second portion having the second thickness grown on the fifth semiconductor layer.

The first and third semiconductor layers may have a first doping concentration and the second semiconductor layer has a second doping concentration. The first doping concentration can be higher than the second doping concentration.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect of the invention can be combined with other aspects. Aspects can be implemented in any convenient form. As used in the specification and in the claims, the singular form of ‘a’, ‘an’, and ‘the’ include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1-13 illustrate cross-sectional views of a process for Flow A to form a semiconductor device using implanted device element regions, according to an embodiment.

FIGS. 14-21 illustrate cross-sectional views of a process for Flow B to form a semiconductor device using epitaxially grown device element regions, according to an embodiment.

FIG. 22 illustrates a flow diagram of an example method for manufacturing a semiconductor device using the process flows described in connection with FIGS. 1-21, according to an embodiment.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Disclosed herein are embodiments related to one or more transistor structures each having vertically stacked S/D structures and a channel structure. In some embodiments, the S/D structures and the channel structure are vertically stacked on top of one another, which can collectively occupy the inner portion (e.g., center area or region) of respective one or more vertical transistor devices. A metal structure may surround at least a portion of the transistor structure. Based on such structures, the transistor structure, as disclosed herein, may be formed as a gate-all-around (GAA) transistor structure, where a gate layer (e.g., gate electrode) may surround at least one S/D structure and/or a channel structure. In one aspect, any number of the disclosed vertical metal structures can be laterally (e.g., side-by-side) arranged with each other and vertically stacked on top of one another, thereby forming an array of transistor structures having improved characteristics in an area-efficient manner. For example, with two different conductive types of the disclosed transistor structure stacked on top of one another, a complementary field-effect-transistor structure can be formed. In another example, a similar conductive type of the disclosed transistor structure can be laterally and/or vertically stacked with respect to each other. In one aspect, an arrangement of the gate layer formed around the metal structures can be flexibly configured. For example, the gate layer can have a single material (e.g., a conductive oxide material) or more than one material (e.g., a conductive oxide material wrapping around a 2D material). Conductive oxide materials/2D materials can allow significant boost in performance relative to silicon (Si), such that the transistor structures disclosed herein may have improved performance or characteristics (e.g., improved transconductance (gm), improved gain bandwidth (Ft), improved saturation current (Idsat), etc.).

Reference will now be made to the Figures, which for the convenience of visualizing the fabrication techniques described herein, illustrate a substrate undergoing a process flow in cross-sectional views. Unless expressly indicated otherwise, each Figure represents one (or a set) of fabrication steps in a process flow for manufacturing the devices described herein. In the cross-sectional views of the Figures, connections between conductive layers or materials may be shown. However, it should be understood that these connections between various layers and masks are merely illustrative, and are intended to show a capability for providing such connections and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, although certain figures show various layers defining transistor structures or other electric structures in a circular configuration, other shapes are also contemplated, and indeed the techniques described herein may be implemented in any shape or geometry.

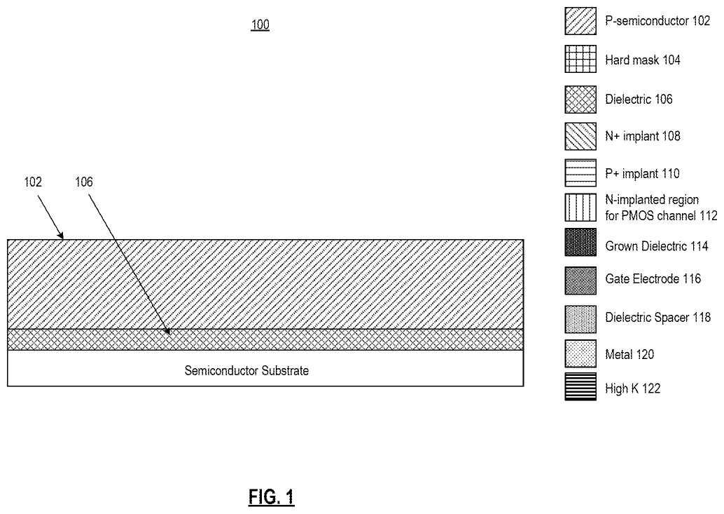

FIGS. 1-13 illustrate cross-sectional views of a process for Flow A to form a semiconductor device using implanted device element regions. Each of the FIGS. 1-13 generally refers to one or more process steps in a process flow of Flow A, each of which is described in detail in connection with the respective Figure. For the purposes of simplicity and ease of visualization, some reference numbers may be omitted from some Figures. As used herein, the terms “first,” “second,” “third,” and “fourth” with respect to particular structures of the semiconductor device shown in FIGS. 1-13 may be used for the purposes of simplicity and can be interchangeable between formations of different structures. For example, a “first,” “second,” and “third” metal structure may refer to the same or different metal structures formed at different processes of the flow. Hence, the terms “first,” “second,” and “third” can be used interchangeably, repetitively (e.g., in different flows), or for different types of structures (e.g., source/drain (S/D) structures, dielectric structures, metal structures, gate structures, etc.).

FIG. 1 illustrates a cross-sectional view 100 of a semiconductor device including materials and/or structures formed above a substrate. The substrate may be active or passive and may comprise dielectric, conductive, or semiconductive materials or any combination thereof. The substrate may be referred to as a base substrate or its respective material or composition. The substrate may remain in the final structure or may be removed during or after the formation of the VFET structure. One or more dielectric materials 106 (e.g., shown as “Dielectric” in the legend) may be provided on the substrate, among other portions of the transistor structure, to isolate the transistor structure from the underlying substrate. The dielectric material 106 (e.g., dielectric layer) may sometimes be referred to as an isolation layer, insulation layer, among other similar terms. The dielectric material 106 can be formed or composed of any type of dielectric material described herein that is capable of being disposed, patterned, or otherwise provided on the various layers described herein. Some examples of dielectric materials can include, but are not limited to, oxide materials.

Above the dielectric material 106, a channel material 102 (e.g., shown as “P-semiconductor” in the legend) can be formed or deposited above the dielectric material 106. Although the channel material 102 is labeled as a P-semiconductor, the channel material 102 can serve as a base material to form an N-type transistor and/or a P-type transistor. For example, a first portion of the channel material 102 (kept in P-type) can serve as the channel material for an N-type transistor configured in enhancement mode, while a second portion of the channel material 102 (converted to N-type) can serve as the channel material for a P-type transistor configured in enhancement mode, which will be discussed in further detail below. The channel material 102 can be separated or isolated from the underlying substrate by the dielectric material 106 having a predefined thickness (e.g., configurable as desired by the manufacturing process). The channel material 102 can include or be formed with one or more materials, such as silicon, germanium, and gallium arsenide, among others.

The materials and structures, such as the semiconductor substrate, channel material 102, and dielectric material 106 can be formed as a vertical structure (e.g., vertical transistor) in any suitable shape. For instance, the materials and structures discussed herein can form a transistor having a cylindrical shape, cuboid shape, spherical shape, among other 3D shapes.

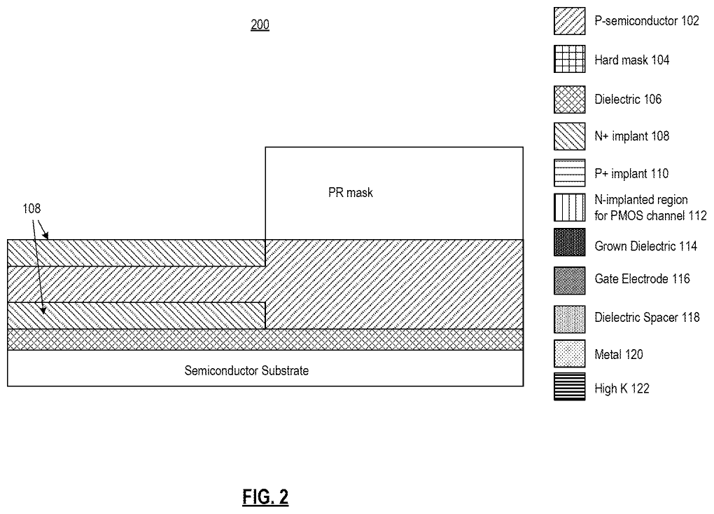

FIG. 2 illustrates a cross-sectional view 200 of the semiconductor device having implanted materials. Subsequent to forming the channel material 102, a mask (e.g., of a photoresist (PR) or other suitable masking material) may be formed above at least a portion of the channel material 102. In this case, the mask can be formed on the right portion of the semiconductor device, such that removal, additional, or replacement of materials can be performed within the opening regions (e.g., the left region of the semiconductor device). For example, at least one suitable masking technique can be used to deposit the mask (e.g., mask material or mask layer) above the channel material 102 as shown in FIG. 2. Similar masking technique(s) can be used herein to form a mask above various materials or structures.

Upon forming the mask, one or more dopants 108 (e.g., shown as “N+ implant” in the legend) can be implanted into or in place of portions of the channel material 102. To implant the dopant materials 108, one or more suitable implant techniques can be utilized, such as an energy implantation technique (e.g., ion implantation technique), among others. Herein, an energy implantation technique can be used for the purposes of providing examples. For example, the ions of a certain element (e.g., dopant material 108) can be accelerated into a target location (e.g., a solid target). The ions may not penetrate through the formed mask. As such, the ions may penetrate within or through the channel material 102 to implant the dopant material 108. The depth of the implantation for the dopant material 108 (or other materials) can be based on the energy generated to accelerate the ion. In this case, the ions may traverse from top to bottom of the channel material 102. Hence, given the depth or thickness of the deposited channel material 102, the energy can be adjusted to deposit multiple layers of the dopant materials 108 at desired levels, positions, or depths of the channel materials 102. Increasing the energy can result in lower positioning implantation of the dopant material 108 in the channel material 102. Decreasing the energy can result in higher positioning implantation of the dopant material 108 in the channel material 102.

The dopant materials 108 can correspond to S/D structures (e.g., S/D materials) associated with a conductive type (e.g., type of transistor device). Although the Figures show the dopant material 108 is labeled as an N implant (e.g., for an N-type transistor device, such as an NMOS), the dopant materials 108 may be formed for any other types of transistor devices, such as a PMOS. In various implementations and examples discussed herein, the first and second S/D structures can have a first conductive type and the first channel structure (e.g., channel material 102) can have a second conductive type. The dopant material 108 (e.g., first metal material) below or underneath the remaining channel material 102 may be referred to as a first S/D structure. The dopant material 108 (e.g., second metal material) formed above or on top of the channel material 102 can be referred to as a second S/D structure. The first and second S/D structures can be the source and the drain of a transistor device.

The mask may be removed once the dopant materials 108 have been implanted into the transistor device. The left portion of the semiconductor device where the dopant materials 108 are implanted for constructing the S/D structures can correspond to a first transistor device. The right portion of the semiconductor device where the mask is removed may correspond to a second transistor device. Hereinafter, one or more masks and etching techniques can be used as discussed above to isolate at least a portion of the semiconductor device from the etching, deposition, filming, or implantation techniques discussed herein.

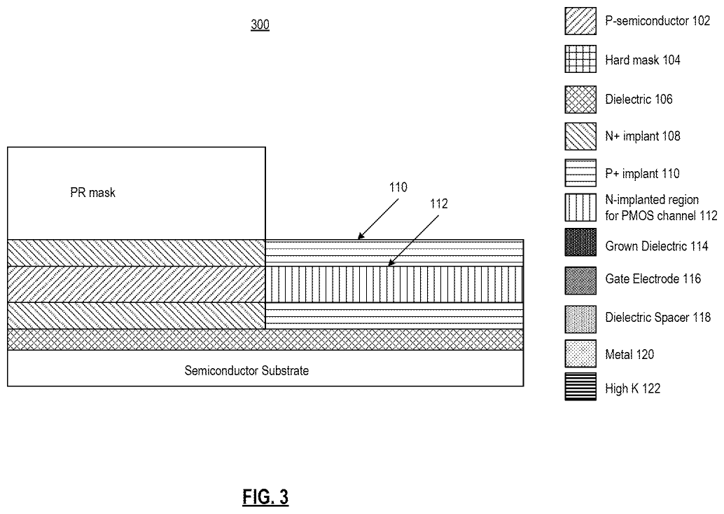

FIG. 3 illustrates a cross-sectional view 300 of the semiconductor device having additional implanted materials. After removing the mask from the portion (e.g., right portion) corresponding to the second transistor device, a mask can be formed above the portion corresponding to the first transistor device. In this case, the mask can be formed above the dopant material 108 (e.g., the second S/D structure above the channel material 102). Using a number of suitable implantation techniques, dopant materials 110 (e.g., shown as “P+ implant” in the legend) and channel material 112 (e.g., shown as N-implanted region for PMOS channel”) can be implanted to construct the second transistor device. Similar implantation techniques can be applied to implant the materials of FIG. 3 (e.g., the dopant material 110 and/or channel material 112) as the metal material 108.

The implanted channel material 112 can be interposed between dopant materials 110. For example, the dopant material 110 (e.g., third metal material or third S/D structure) can be below the channel material 112. The dopant material 110 (e.g., fourth metal material or fourth S/D structure) can be above the channel material 112. Therefore, the channel material 112 can be interposed between the third and fourth S/D structures corresponding to the dopant materials 110.

The dopant materials 110 may be aligned laterally to the dopant materials 108. The channel material 112 may be aligned laterally to the channel material 102. In various implementations, the dopant materials 110 and/or the channel material 112 may not be aligned with the respective dopant materials 108 and/or the channel material 102. Once these materials are implanted, the mask formed above the first transistor device can be removed.

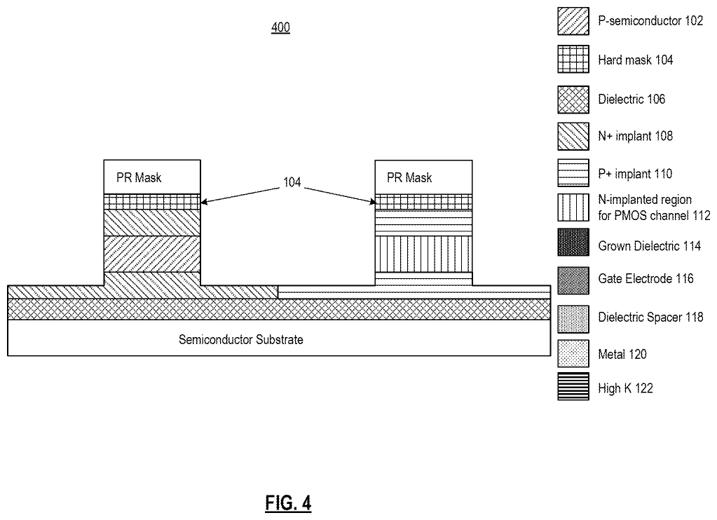

FIG. 4 illustrates a cross-sectional view 400 of the semiconductor device including a hard mask. After forming the respective channel structures (e.g., channel materials 102, 112) and S/D structures (e.g., dopant materials 108, 110), a mask material 104 (e.g., shown as “hard mask” in the legend) can be deposited above the dopant materials 108, 110 of the respective transistor devices. The mask material 104 can include or be formed using any suitable material, such as silicon (e.g., silicon nitrate, silicon dioxide, or silicon carbide), metal, dielectric, among others. The mask material 104 can overlap or form above the first and second transistor devices.

One or more masks can be formed above the mask material 104 using at least one suitable masking technique. Once the masks are formed, one or more etch techniques may be performed to remove the portion of the underlying materials aligned with the opening in the mask (e.g., portions of underlying materials not covered with the mask). Any type of suitable etching techniques may be used, including but not limited to dry etching, wet etching, or plasma etching techniques. The mask may be removed once the etching process to remove a portion of the materials is completed. Hereinafter, to form remove one or more described materials, one or more masks and etching techniques can be used as discussed above. The etching process can remove materials in any geometry, such as vertically or diagonally. The dimension (e.g., width or diameter) of the masks can correspond to the dimension of the opening (e.g., removed portions of the materials) or the dimension of the underlying materials of the masks.

As shown, using the mask and etching process, portions of the mask material 104, dopant materials 108, 110, and channel materials 102, 112 can be removed or otherwise patterned. In this case, the opening formed via the etching process can be vertically extended to at least the channel materials 102, 112. A portion of the bottom dopant materials 108, 110 (e.g., a portion of the first S/D structure and the third S/D structure) may not be removed, such that this portion remains laterally extended beyond the dimension of the mask. For example, a first portion of the dopant materials 108, 110 can be removed according to the dimension of the mask, thereby having a sidewall that aligns with the channel materials 102, 110 and the dopant materials 108, 110 above the channel materials 102, 110. A second portion of the dopant materials 108, 110 may not be removed. Hence, the second portion of the dopant materials 108, 110 can be disposed below the first portion and laterally extends beyond the sidewall of the first portion. The first and second portions of the dopant materials 108, 110 underlying the channel materials 102, 112 can include similar or different heights. In various implementations, this etching process may not remove materials down to at least one of the semiconductor substrate and/or the dielectric material 106.

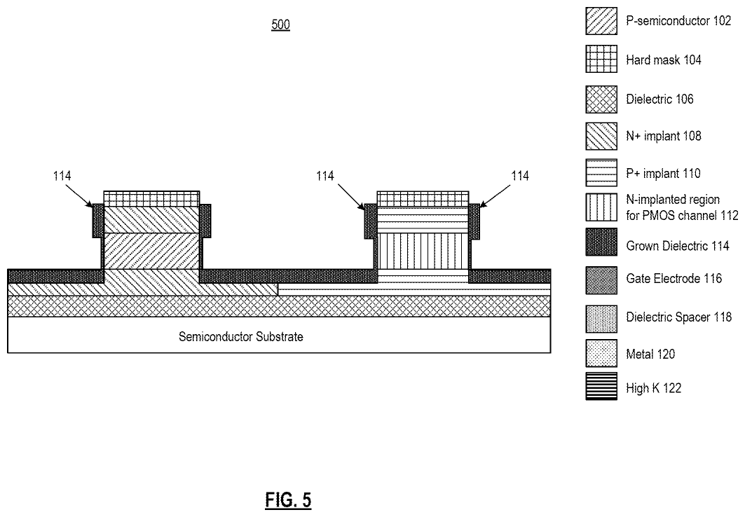

FIG. 5 illustrates a cross-sectional view 500 of the semiconductor device including a dielectric layer. Within the opening formed subsequent to the etching process, dielectric material 114 (e.g., shown as “grown dielectric” in the legend) can be grown, deposited, or formed as a layer within the opening, such as above the second portion of the bottom dopant materials 108, 110 (e.g., the dopant materials 108, 110 below the channel materials 102, 112). Further, the dielectric material 114 can be disposed along the sidewall of the dopant materials 108, 110 and the channel material 102, 112. The dielectric material 114 may include similar or different composition as the dielectric material 106.

As shown, the dielectric material 114 may be thicker around the region (e.g., S/D structures) of the dopant materials 108, 110 relatives to the region (e.g., channel structures) of the channel material 102, 112. For instance, based on an oxidation process, a heavily doped region (e.g., dopant material 108, 110) may grow thicker dielectric material 114 compared to a lightly doped region (e.g., channel material 102, 112). This may be due to the first and second S/D structures having a higher doping concentration than the first channel structure, and the third and fourth S/D structures have a higher doping concentration than the second channel structure. In some cases, the thickness of the dielectric material 114 around the dopant materials 108, 110 and the channel materials 102, 112 can be modified as desired, using at least one suitable etching technique to remove excess dielectric material 114 or deposition technique to add the dielectric material 114. With the dielectric material 114 surrounding the dopant materials 108, 110 and the channel materials 102, 112, the oxidation rate of the S/D structures can be enhanced relative to the channel structures.

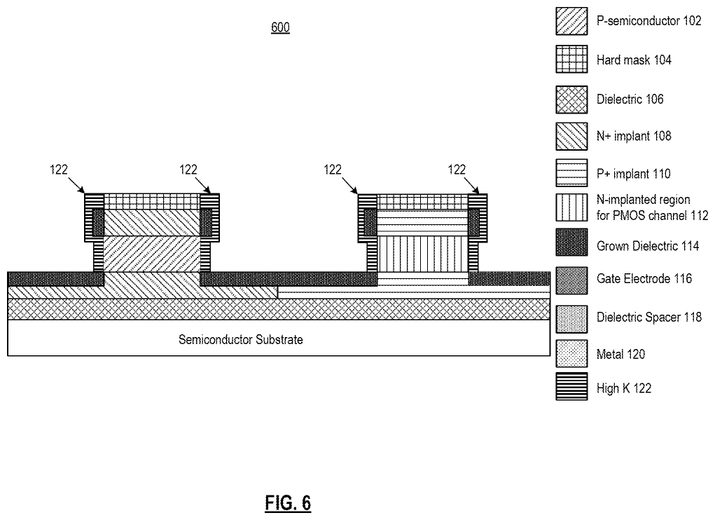

FIG. 6 illustrates a cross-sectional view 600 of the semiconductor device including a gate dielectric layer without the grown dielectric on the channel structure. In this case, after depositing the dielectric material 114 around the dopant materials 108, 110 (e.g., S/D structures) and the channel materials 102, 112 (e.g., channel structures), the dielectric material 114 can be removed from the channel structures. Without the dielectric material 114 on the channel structures, the thickness of the dielectric material 114 around the S/D structures can be reduced. The removal or reduction of the dielectric material 114 can be performed using at least one suitable etching technique.

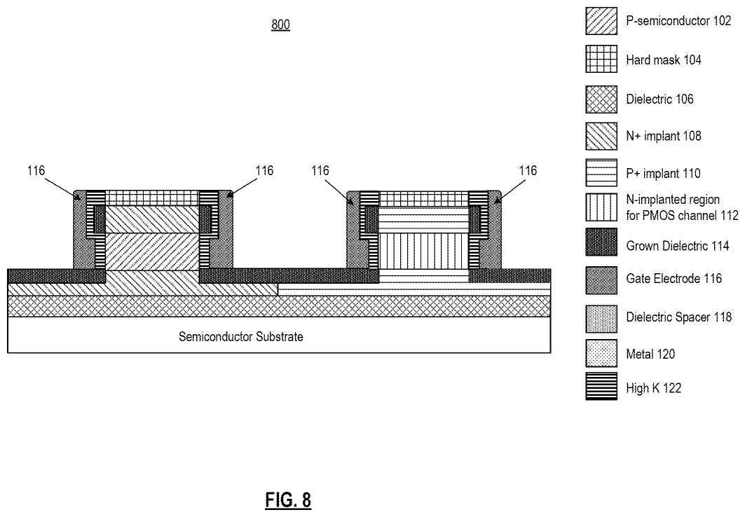

Subsequent to etching the dielectric material 114, a high-k dielectric 122 (e.g., shown as “high k” in the legend or sometimes referred to as gate dielectric layer, high-k material, structure, or layer) can be selectively deposited or lined within the opening. For example, the high-k dielectric 122 can be formed or grown around the respective sidewalls of the dopant materials 108, 110, the channel materials 102, 112, the dielectric material 114, and/or the mask material 104. The high-k dielectric 122 can be grown with a predetermined thickness, such as to separate a gate material (e.g., as shown in FIG. 8) or other materials from at least one of the dopant materials 108, 110, and/or the channel materials 102, 112. As shown, the high-k dielectric 122 can be extended in the vertical direction from the mask material 104 to at least the surface of the dielectric material 114 deposited over the second portion of the first and third S/D structures (e.g., the second portion of the bottom dopant materials 108, 110).

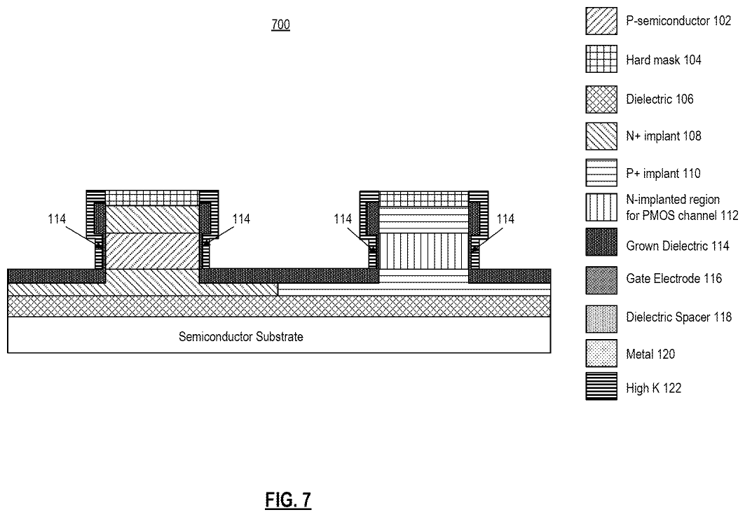

FIG. 7 illustrates a cross-sectional view 700 of the semiconductor device including a gate dielectric layer with the grown dielectric on the channel structure. In this case, the dielectric material 114 disposed within the opening and around the sidewalls of the S/D structures, and the channel structure may not be etched or removed. In various embodiments, additional thickness of the dielectric material 114 may be added above or around the dielectric material 114 deposited in FIG. 5. Hence, the high-k dielectric 122 can be deposited around the dielectric material 114 along the respective sidewalls of the channel structure and the S/D structures. A similar process as FIG. 6 can be performed to deposit the high-k dielectric 122. Herein, for purposes of providing examples, the Figures can illustrate examples of the semiconductor device with the dielectric material 114 removed from the channel structure and thinned down on the S/D structures. Alternatively, in some other example, the dielectric material 114 may be maintained herein.

FIG. 8 illustrates a cross-sectional view 800 of the semiconductor device including a gate electrode. Upon forming the high-k dielectric 122, a gate material 116 (e.g., shown as “gate electrode” in the legend) can be deposited within the opening. The gate material 116 may be referred to as a gate structure. The deposition of the gate material 116 can be performed using at least one suitable deposition technique. In some cases, the gate material 116 can be etched using at least one suitable etching technique subsequent to the deposition. The gate material 116 can be disposed around at least one sidewall of the high-k dielectric 122, the channel materials 102, 112, and/or the metal materials 108, 110. Therefore, the high-k dielectric 122 can separate the gate material 116 from the S/D structure(s) and/or the channel structures. The gate material 116 can extend vertically from at least the mask material 104 to the surface of the dielectric material 114 above the first and third S/D structures.

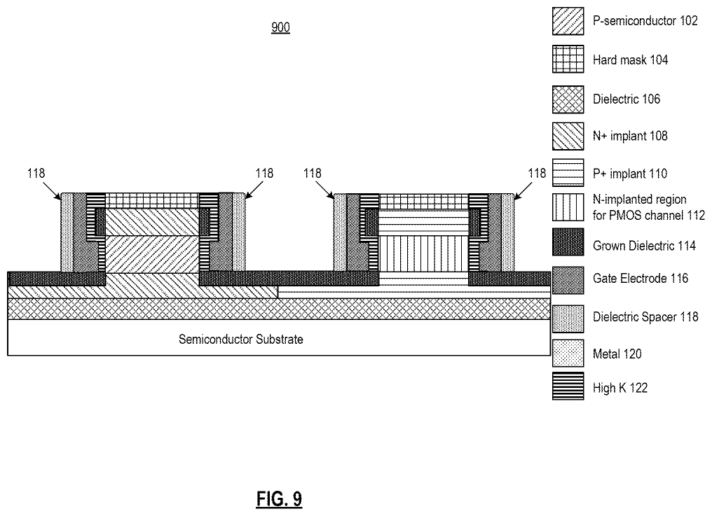

FIG. 9 illustrates a cross-sectional view 900 of the semiconductor device including a dielectric spacer. A dielectric material 118 (e.g., shown as “dielectric spacer” in the legend) can be formed or deposited using at least one suitable deposition technique and/or etching technique. The dielectric material 118 can be composed of similar or different materials from the dielectric material 114 and/or dielectric material 106. The dielectric material 118 can be formed similar to the formation of the gate material 116, for example. The dielectric material 118 can be disposed around the sidewall of at least one of the metal materials 108, 110, channel materials 102, 112, dielectric material 114, high-k dielectric 122, and/or gate material 116. The dielectric material 118 can extend vertically, such as having a similar height as at least one of the gate material 116 and/or the high-k dielectric 122. In some cases, the dielectric material 118 may be optional, such that the steps hereinafter may or may not include the dielectric material 118 in the fabricated semiconductor device.

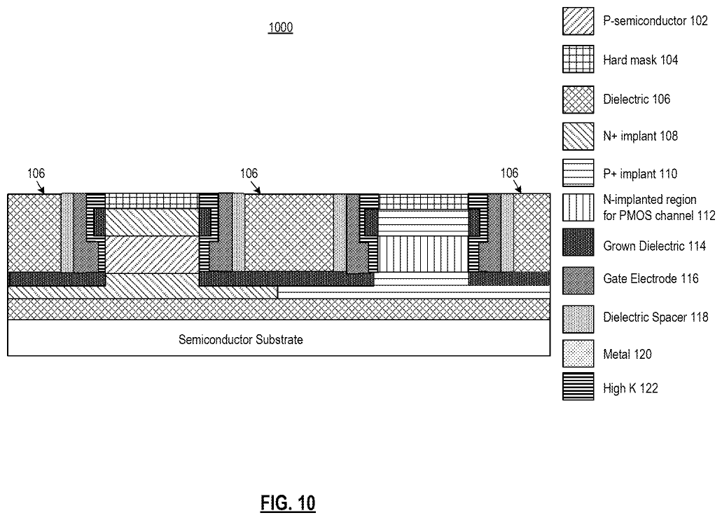

FIG. 10 illustrates a cross-sectional view 1000 of the semiconductor device including the opening filled with the dielectric material 106. Upon depositing the dielectric material 118, the dielectric material 106 can be deposited into the remaining opening for isolation of the respective transistor devices. The dielectric material 106 can be deposited using at least one suitable deposition technique. Following the deposition of the dielectric material 106, the semiconductor device can be polished using at least one suitable polishing technique, such as chemical mechanical planarization (CMP), among others.

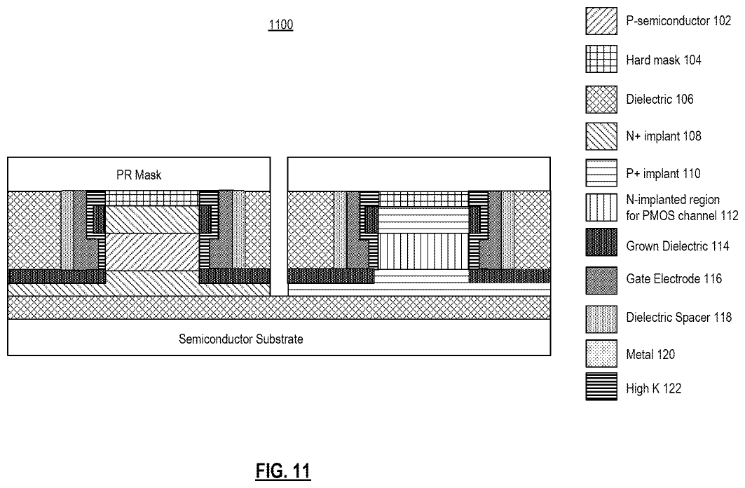

FIG. 11 illustrates a cross-sectional view 1100 of the semiconductor device including another opening. One or more masks can be formed above the semiconductor device, such as above the mask material 104, high-k dielectric 122, gate material 116, dielectric material 118 and/or dielectric material 106. The mask can be formed using at least one suitable masking technique. As shown, the mask can be used to form an opening (e.g., a second opening) through the materials, separating the first and second transistor devices. For example, upon forming the masks, at least one suitable etching technique can be performed at the opening defined by the masks. A portion of the dielectric materials 106, 114 and a portion of the metal materials 108, 110 can be removed to form the opening to create a diffusion break between the two transistor devices (e.g., NMOS and PMOS devices). The opening can extend from the surface of the dielectric material 106 interposed between the first and second transistor devices to at least the surface of the dielectric material 106 underlying the transistor devices. In this case, the first S/D structure and the second S/D structure can be decoupled relative to the gate structure (e.g., the gate material 116) to reduce its capacitance (e.g., of the gate structure). The mask can be removed upon completing the etching process.

In some implementations, the masking and/or etching technique may not be performed, such that the bottom metal material 108 of the first transistor device can remain in contact or connection with the bottom metal material 110 of the second transistor device. For instance, an NMOS can be in connection with another NMOS, a PMOS can be in connection with another PMOS, etc. In another example, a local interconnect may be formed between the metal materials 108, 110 via at least one suitable deposition technique. In this example, the S/D structure of a transistor device can be in connection with the D/S (e.g., drain/source) structure of the other transistor device, among others, to extend the transistor devices (e.g., multiple NMOS or PMOS side-by-side).

In various implementations, the opening formed via the etching technique can be used to deposit one or more metal structures or materials, such as to vertically route at least one of the metal materials 108, 110 (e.g., first and/or third S/D structures) for (e.g., electrical) connection above the transistor devices. The vertical routing can be formed with one or more metal structures deposited using at least one suitable deposition technique, for example. By enabling vertical routing of the S/D structures to the base (e.g., for external connections or connections to other materials), horizontal etching can be avoided. Although various implementations can be leveraged via the opening, for the purposes of providing examples herein, the opening can be filled with dielectric material 106 to create the diffusion break between the transistors.

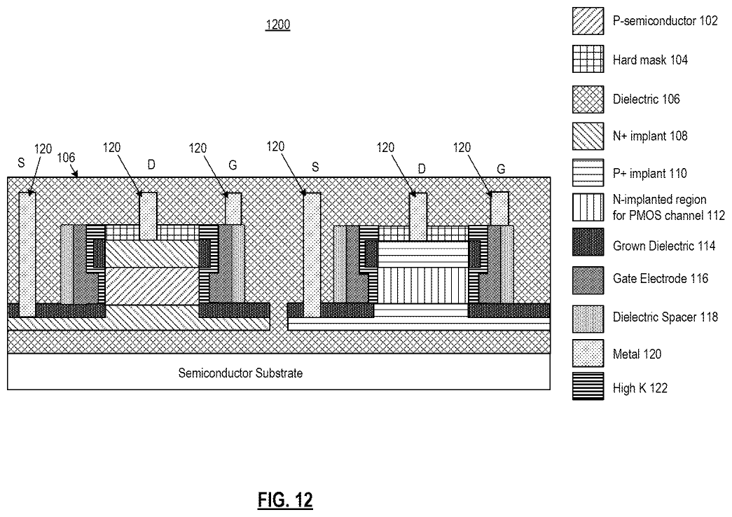

FIG. 12 illustrates a cross-sectional view 1200 of the semiconductor device including vertical metal routings. Subsequent to creating the diffusion break, various openings can be formed similarly as described in FIG. 11, such as using at least one suitable masking technique and etching technique. As shown, an additional layer of the dielectric material 106 can be deposited over the semiconductor device. Openings can be formed extending from the surface of the dielectric material 106 above the semiconductor device to a portion of the surface of the S/D structures and gate structures.

For example, the openings can extend to the surface of the first S/D structure (e.g., bottom metal material 108, shown as the source), the second S/D structure (e.g., top metal material 108, shown as the drain), the third S/D structure (e.g., bottom metal material 110, shown as a source), and/or the fourth S/D structure (e.g., top metal material 110, shown as the drain). The openings can further extend to the surface of the gate materials 116 (e.g., first gate structure and second gate structure of the respective transistor devices).

Via the openings, metal materials 120 (e.g., shown as “metal 120” in the legend) can be deposited in the openings using at least one suitable deposition technique. Upon the deposition, the S/D structures and/or gate structures can be (e.g., electrically) routed vertically, extending above the transistor devices. An additional layer of the dielectric material 106 can be deposited above the semiconductor device. Hence, the semiconductor device shown in FIG. 12 can be formed.

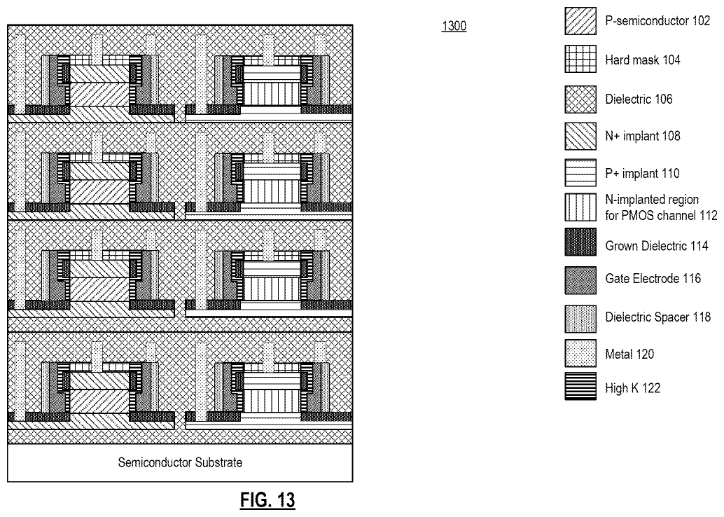

FIG. 13 illustrates a cross-sectional view 1300 of the semiconductor device including a stack of transistor devices. Above each transistor device, one or more processes discussed in FIGS. 1-12 can be performed herein to form at least one additional stack of transistors above another transistor. Although the stack shows four layers or levels of transistor devices (e.g., each level can include more than two transistor devices extending horizontally), the stack of the semiconductor device can include any number of levels. As such, by performing the operations described in at least FIGS. 1-13, a high-density 3D transport device nanosheet having N number of vertically bonded transistors can be formed.

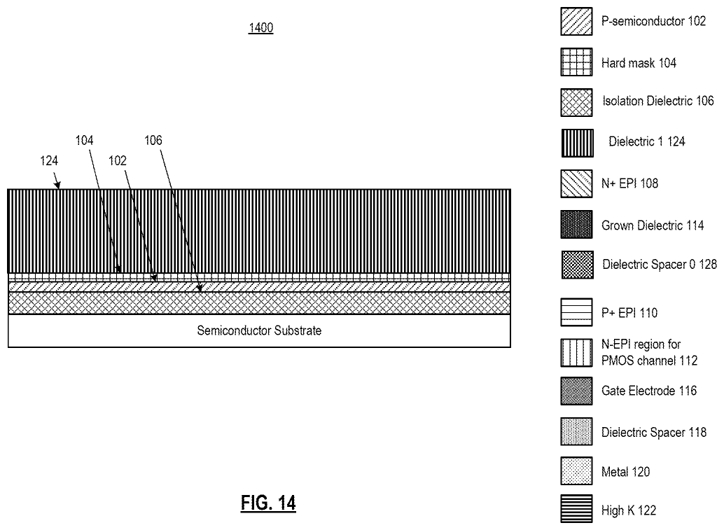

FIGS. 14-21 illustrate cross-sectional views of a process for Flow B to form a semiconductor device using epitaxial grown device element regions. Each of the FIGS. 14-21 generally refers to one or more process steps in a process flow of Flow B, each of which is described in detail in connection with the respective Figure. For the purposes of simplicity and ease of visualization, some reference numbers may be omitted from some Figures. As used herein, the terms “first,” “second,” “third,” and “fourth” with respect to particular structures of the semiconductor device shown in FIGS. 14-21 may be used for the purposes of simplicity and can be interchangeable between formations of different structures. For example, a “first,” “second,” and “third” metal structure may refer to the same or different metal structures formed at different processes of the flow. Hence, the terms “first,” “second,” and “third” can be used interchangeably, repetitively (e.g., in different flows), or for different types of structures (e.g., source/drain (S/D) structures, dielectric structures, metal structures, gate structures, etc.). One or more operations discussed in FIGS. 14-21 can be similar to or in conjunction with FIGS. 1-13, for example.

FIG. 14 illustrates a cross-sectional view 1400 of a semiconductor device including materials and/or structures formed above a substrate. The substrate may be similar to or different from the semiconductor substrate described in FIG. 1. The dielectric material 106 may be provided, formed, or deposited on the substrate, among other portions of the transistor structure, to isolate the transistor structure from the underlying substrate. The channel material 102 may be provided, formed, or deposited over the dielectric material 106. The mask material 104 can be provided, formed, or deposited over the channel material 102. The structure of these materials (e.g., having a hard mask above the dielectric material 106 and the channel material 102) can enable epitaxy (EPI) to be grown in selective regions for different device types. A dielectric material 124 (e.g., shown as “dielectric 1” in the legend) can be provided, formed, or deposited over the mask material 104. The dielectric material 124 can be composed of similar materials to or different materials from other dielectric materials (e.g., dielectric material 106, dielectric material 114, and/or dielectric material 118). These materials can be deposited using at least one suitable deposition technique described herein.

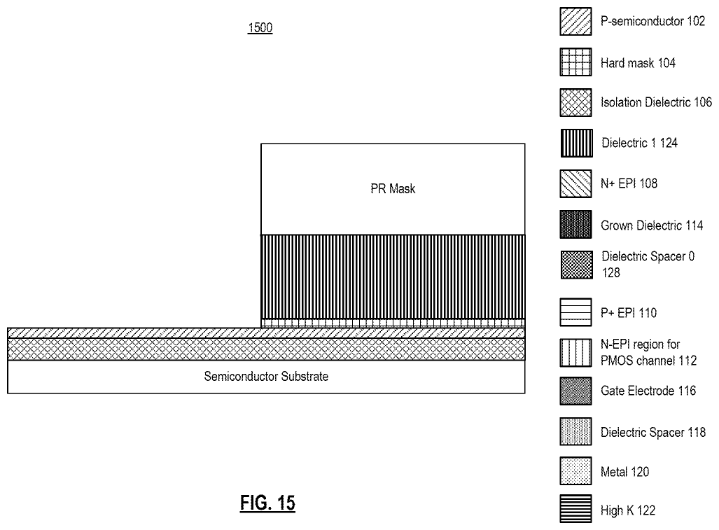

FIG. 15 illustrates a cross-sectional view 1500 of the semiconductor device with a portion of the materials associated with a first transistor device removed. At least one mask can be formed above a portion of the provided materials and/or structures using a suitable masking technique, such as similar to FIG. 2. For example, the mask can be formed above a portion of the materials associated with a second transistor device. Using at least one suitable etching technique, a portion of the dielectric material 124 and a portion of the mask material 104 can be removed, as shown. These portions of the dielectric material 124 and the mask material 104 can be associated with the first transistor device. Hence, a portion of the channel material 102 surface (e.g., on the left side of the semiconductor device) can be exposed. In some cases, the channel material 102 can also be removed using the etching technique to expose a portion of the underlying dielectric material 106 surface. The etched portion can form an opening in the semiconductor device. The mask can be removed once the etching process is completed.

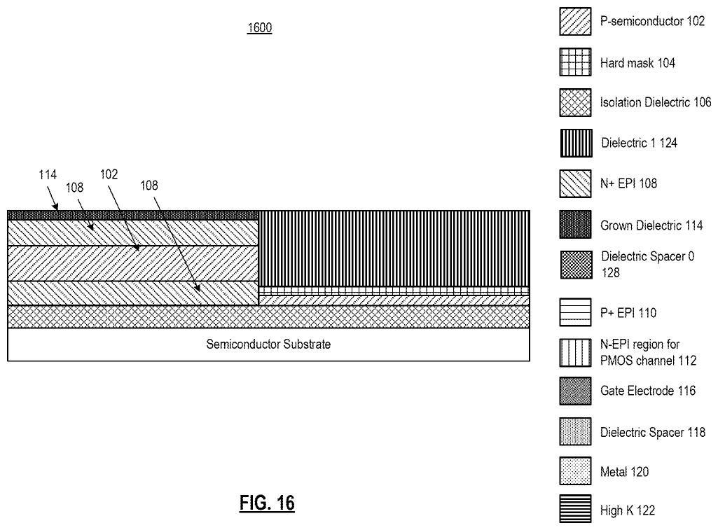

FIG. 16 illustrates a cross-sectional view 1600 of the semiconductor device including the first semiconductor device. For example, within the opening, at least one suitable deposition technique can be utilized to deposit the metal material 108 (e.g., shown here as “N+ EPI” in the legend), the channel material 102, and/or the dielectric material 114 (e.g., grown dielectric material oxidation). The metal material 108 (e.g., N+ EPI) can be similar to the metal material 108 (e.g., N+ implant) of at least FIG. 2. Further, the layers of the metal material 108 and the channel material 102 can be similar to FIG. 2.

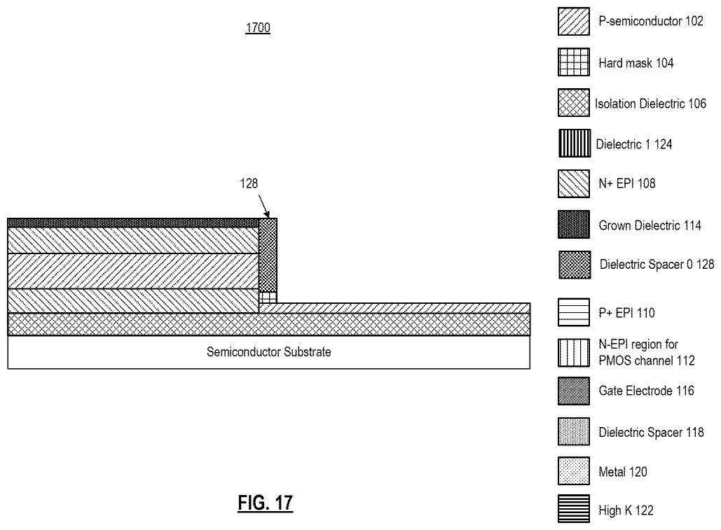

FIG. 17 illustrates a cross-sectional view 1700 of the semiconductor device with a portion of the materials associated with the second transistor device removed. At least one suitable masking technique and etching technique can be performed similarly to FIG. 15. For example, a mask can be formed above the dielectric material 114 via at least one masking technique. At least one etching technique can be performed to remove the dielectric material 124 from the portion associated with the second transistor. Once the dielectric material 124 is removed, dielectric material 128 (e.g., shown as “dielectric spacer 0”) can be formed or deposited over a portion of the mask material 104. In some cases, the dielectric material 128 can be disposed above the surface of the mask material 104, such that the dielectric material 128 is extending laterally above the mask material 104.

An additional or alternative mask can be formed above the dielectric material 114 and a portion of the dielectric material 128 (e.g., the portion shown in FIG. 17). At least one suitable etching technique can be performed to remove a portion of the dielectric materials 114, 128, thereby exposing the surface of the underlying channel structure 102. In some cases, the etching process can include removing a portion of the underlying channel structure 102 to expose the surface of the dielectric material 106. The mask can be removed in response to completing the etching operation that forms the opening shown in FIG. 17.

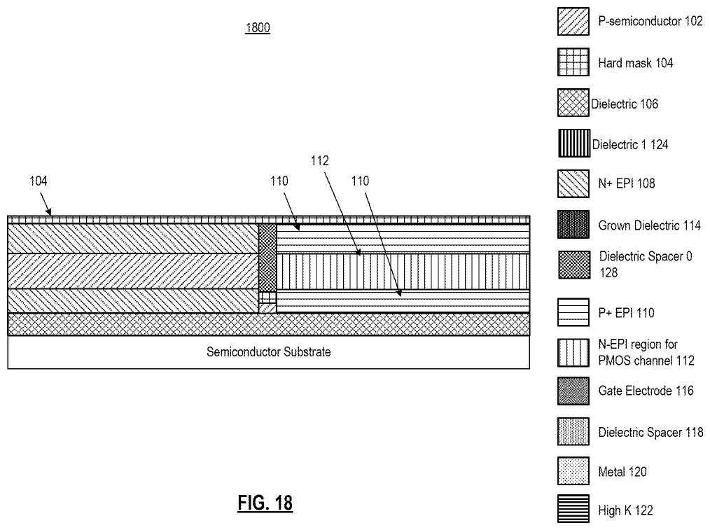

FIG. 18 illustrates a cross-sectional view 1800 of the semiconductor device including the second transistor device. Within the opening, one or more materials to form the second transistor device can be deposited using at least one suitable deposition technique. For example, the metal materials 110 (e.g., shown as “P+ EPI” in the legend, similar to the “P+ implant”) and/or the channel material 112 (e.g., shown as “N-EPI region for PMOS channel,” similar to “N-implanted region for PMOS channel”) can be deposited via the opening to form the second transistor device. The metal materials 110 and the channel material 112 can be formed or grown, such that the channel material 112 is interposed between two metal materials 110 (e.g., third and fourth S/D structures).

Once the metal materials 110 and the channel material 112 are deposited to form a structure similar to FIG. 3, for example, the semiconductor device (e.g., the first and second transistors) can be polished using at least one suitable polishing technique, such as CMP. In various implementations, the dielectric material 114 above the metal material 108 (e.g., second S/D structure) can be removed or replaced with an additional layer of metal material 108. The metal materials 108 can be aligned laterally to the metal materials 110. The channel material 102 may be aligned laterally with the channel material 112. After the polish, a mask material 104 can be deposited over the transistors, such as above the second and fourth S/D structures, and the dielectric material 128.

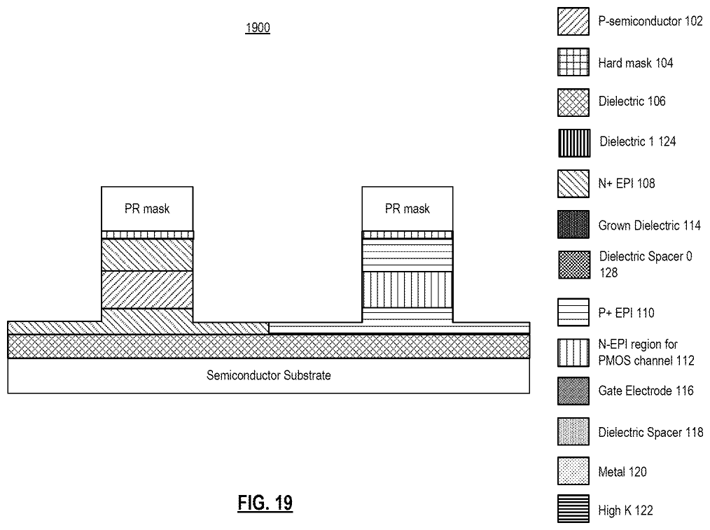

FIG. 19 illustrates a cross-sectional view 1900 of the semiconductor device having multiple openings defining the dimensions (e.g., width, length, or diameter) of the transistor devices. One or more masks can be formed above portions of the mask material 104 using at least one suitable masking technique. The dimension of the masks can represent the dimension of the first and/or second transistors. Once the masks are formed, one or more etch techniques may be performed to remove the portion of the underlying materials, such as using at least one etching technique similar to or in conjunction with FIG. 4.

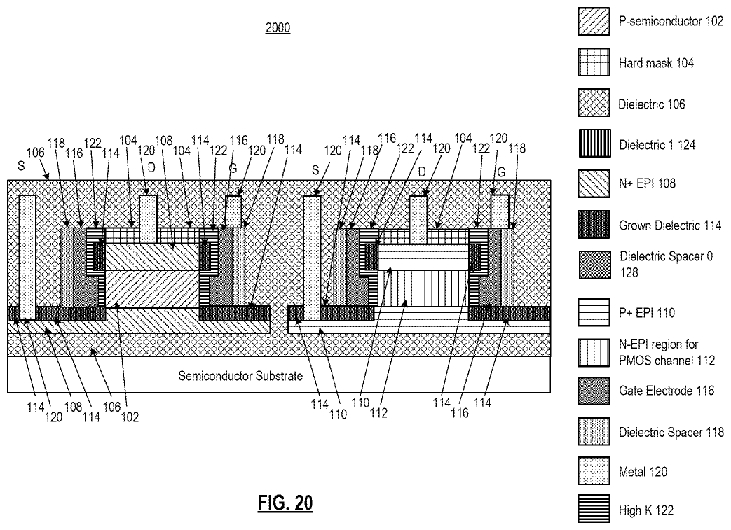

As shown, using the mask and etching process, portions of the mask material 104, metal materials 108, 110, and channel materials 102, 112 can be removed. The opening formed from the etching process can be vertically extended to a portion of the channel materials 102, 112. The depth of the opening can extend similarly to FIG. 4, such that a first portion of the first and third S/D structures are removed while a second portion of the first and third S/D structures can remain laterally extended beyond the sidewall of the first portion. For example, the sidewall of the first portion of the first and third S/D structures can vertically align with the respective channel structure and the respective second and fourth S/D structures. As such, the dimension of the transistors can be defined according to the dimension of the masks utilized in this process. Subsequently, one or more processes in conjunction with those described in at least FIGS. 5-12 can be performed hereinafter to form the semiconductor device shown in FIG. 20, for example.

FIG. 20 illustrates a cross-sectional view 2000 of the semiconductor device including vertical routing metals. Upon performing one or more operations or processes described in at least FIGS. 5-12, subsequent to the operations of at least FIGS. 14-19, the semiconductor device as shown herein can be formed. As shown, the semiconductor device can include similar features, constructions, elements, structures, or materials as the semiconductor device of FIG. 12, for example. Various materials and structures can be formed using any suitable masking techniques, etching techniques, and/or deposition techniques discussed herein. Hence, at least one of the dielectric material 114, high-k dielectric 122, gate material 116, and/or dielectric material 118 can be formed around the S/D structures and channel structures. Further, the metal materials 120 can be disposed vertically, where each metal material 120 can be in (e.g., electrical) connection with at least one of the S/D structures or gate structures.

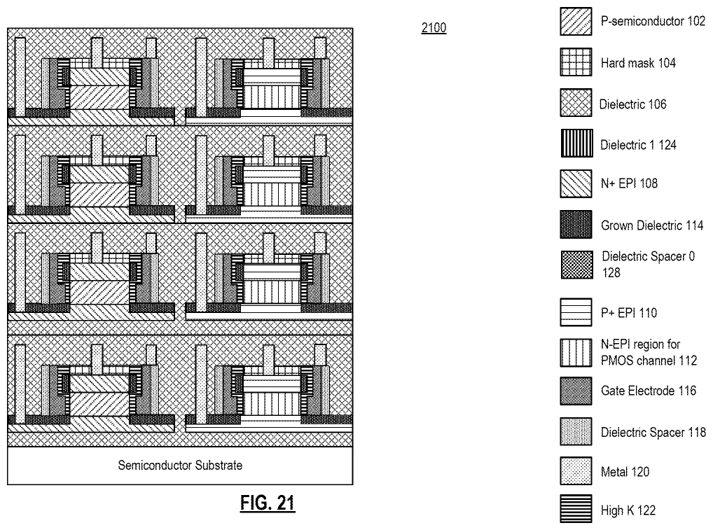

FIG. 21 illustrates a cross-sectional view 2100 of the semiconductor device including a stack of transistor devices. Above each transistor device, one or more processes discussed in FIGS. 14-20 can be performed herein to form at least one additional stack of transistors above another transistor. Although the stack shows four layers or levels of transistor devices (e.g., each level can include more than two transistor devices extending horizontally), the stack of the semiconductor device can include any number of levels. For example, the semiconductor device can include a third transistor device/structure vertically or horizontally disposed with respect to the first transistor device and/or the second transistor device. As such, by performing the operations described in at least FIGS. 14-20, a high-density 3D transport device nanosheet having N number of vertically bonded transistors can be formed.

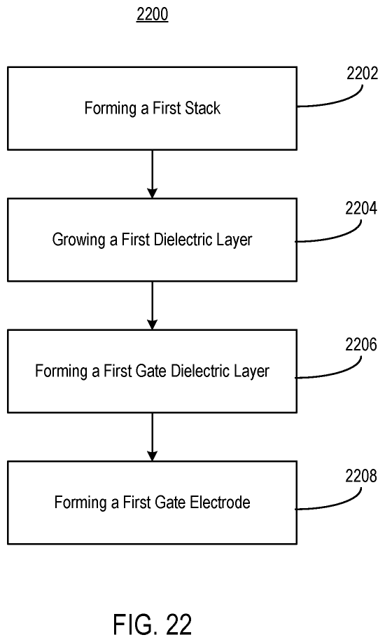

FIG. 22 illustrates a flow diagram of an example method 2200 for manufacturing a semiconductor device using the process flows described in connection with FIGS. 1-21. The method 2200 may include steps 2202-2208. In various embodiments, operations of the method 2200 may be associated with cross-sectional views of an example semiconductor device at various fabrication stages as shown in FIGS. 1-21, respectively, which will be discussed in further detail below. It should be understood that the semiconductor device, such as shown in FIGS. 1-21, may include a number of other devices such as inductors, fuses, capacitors, coils, etc., while remaining within the scope of the present disclosure.

At step 2202, the method 2200 can include forming a first stack. The first stack can include a first semiconductor layer (e.g., first S/D structure) having a first conductive type, a second semiconductor layer (e.g., first channel structure) having a second conductive type, and a third semiconductor layer (e.g., second S/D structure) having the first conductive type. The first conductive type can be the opposite of the second conductive type. The first stack can be a part of a first transistor device/structure.

Concurrent with forming the first stack, the method 2200 can include forming a second stack laterally disposed next to the first stack. The second stack can include a fourth semiconductor layer (e.g., third S/D structure) having the second conductive type, a fifth semiconductor layer (e.g., second channel structure) having the first conductive type, and a sixth semiconductor layer (e.g., fourth S/D structure) having the second conductive type. The second stack can be a part of a second transistor device/structure.

In various embodiments, the first and third semiconductor layers can have a first doping concentration (e.g., a first amount of doping concentration). The second semiconductor layer can have a second doping concentration (e.g., a second amount of doping concentration). The first doping concentration may be higher than the second doping concentration. In some implementations, the first, second, and third semiconductor layers may be doped with a similar doping concentration.

In various implementations, the first semiconductor layer can include a first portion and a second portion. The first portion can include a sidewall vertically aligned with the sidewall of the second and third semiconductor layers. The second portion can be disposed below the first portion and laterally extending beyond the sidewall of the first portion. The fourth semiconductor layer may include separate portions, such as third portion and fourth portion of the fourth semiconductor layer. Similar to the first semiconductor layer, the third portion can include a sidewall vertically aligned with the sidewall of the fifth and sixth semiconductor layers. The fourth portion can be disposed below the third portion and laterally extending beyond the sidewall of the third portion.

At step 2204, the method 2200 can include growing a first dielectric layer (e.g., grown dielectric), such as along at least a portion of the first stack (e.g., around the sidewall of the first stack). A first portion of the first dielectric layer can have a first thickness grown on the first and/or third semiconductor layers (e.g., around the sidewall of the first and/or second S/D structures). A second portion of the first dielectric layer can have a second thickness grown on the second semiconductor layer (e.g., around the sidewall of the first channel structure). The first thickness can be greater than the second thickness based on the doping concentration of the first, second, and third semiconductor layers (e.g., higher doping concentration can result in a greater thickness).

In various implementations, concurrent to growing the first dielectric layer, the method 2200 can include growing a second dielectric layer along at least a portion of the second stack (e.g., around the sidewall of the second stack). A first portion of the second dielectric layer can have a third thickness grown on the fourth and/or sixth semiconductor layers (e.g., around the sidewall of the third and/or fourth S/D structures). A second portion of the second dielectric layer can have a fourth thickness grown on the fifth semiconductor layer (e.g., around the sidewall of the second channel structure). The third thickness can be greater than the fourth thickness based on the doping concentration of the fourth, fifth, and sixth semiconductor layers. In some cases, the third thickness can be similar to the first thickness, and the fourth thickness can be similar to the second thickness.

At step 2206, the method 2200 can include forming a first gate dielectric layer (e.g., first high-k dielectric). The gate dielectric layer can have or be composed of a high-k dielectric material. The first gate dielectric layer can be formed around the sidewall of the first stack, such as around the second semiconductor layer (e.g., first channel structure) and/or a sidewall of the first dielectric layer (e.g., first grown dielectric associated with the first transistor device). Concurrent with forming the first gate dielectric layer, the method 2200 can include forming a second gate dielectric layer (e.g., second high-k dielectric with a similar or different high-k dielectric material as the first high-k dielectric). The second gate dielectric layer can be formed around the sidewall of the second stack, such as around the fifth semiconductor layer (e.g., second channel structure) and/or a sidewall of the second dielectric layer (e.g., second grown dielectric associated with the second transistor device).

At step 2208, the method 2200 can include forming a first gate electrode (e.g., first metal electrode). The first gate electrode can be formed around the first gate dielectric layer (e.g., around the sidewall) and/or the sidewall of the first stack. Concurrent with forming the first gate electrode, the method 2200 can include forming a second gate electrode (e.g., second metal electrode with a similar or different composition from the first metal electrode). The second gate electrode can be formed around the second gate dielectric layer (e.g., around the sidewall) and/or the sidewall of the second stack.)

In various implementations, one or more other transistor devices/structures can be formed or disposed vertically or laterally with respect to the first and/or the second transistor structures. For example, the method 2200 may further include forming a third transistor structure vertically disposed with respect to the first transistor structure. The third transistor structure can include a third stack. The third stack can include a seventh semiconductor layer (e.g., fifth S/D structure), an eighth semiconductor layer (e.g., third channel structure), and a ninth semiconductor layer (e.g., sixth S/D structure). The third channel structure can be disposed above the fifth S/D structure, and interposed between the fifth and sixth S/D structures. The sidewall of a first portion of the fifth S/D structure, a sidewall of the third channel structure, and a sidewall of the sixth S/D structure can be vertically aligned with one another, such as similar to the other stacks (e.g., the first and second stacks). The third transistor structure can include a third metal electrode (e.g., third gate electrode) disposed around the sidewall of the third channel structure and/or the sidewall of the sixth source/drain structure.

In various implementations, the first S/D structure, the second S/D structure, the fifth S/D structure, and the sixth S/D structure can have a first conductive type, and the first channel structure and third channel structure can have a second, opposite conductive type. The conductive types of the S/D structures and channel structures can be selected or modified according to the desired fabrication process or configurations of various transistor structures.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features discussed only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence has any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A semiconductor device, comprising:
a transistor structure comprising:
a first source/drain structure;
a channel structure disposed above the first source/drain structure;
a second source/drain structure disposed above the channel structure, wherein a sidewall of a portion of the first source/drain structure, a sidewall of the channel structure, and a sidewall of the second source/drain structure are vertically aligned with one another; and
a metal electrode disposed around the sidewall of the channel structure and the sidewall of the second source/drain structure.

2. The semiconductor device of claim 1, further comprising:
a second transistor structure laterally disposed next to the transistor structure and comprising:
a third source/drain structure;
a second channel structure disposed above the third source/drain structure;
a fourth source/drain structure disposed above the second channel structure, wherein a sidewall of a first portion of the third source/drain structure, a sidewall of the second channel structure, and a sidewall of the fourth source/drain structure are vertically aligned with one another; and
a second metal electrode disposed around the sidewall of the second channel structure and the sidewall of the fourth source/drain structure.

3. The semiconductor device of claim 2, wherein the first source/drain structure and the second source/drain structure have a first conductive type, while the channel structure has a second, opposite conductive type, and wherein the third source/drain structure and the fourth source/drain structure have the second conductive type, while the second channel structure has the first conductive type.

4. The semiconductor device of claim 3, wherein the first source/drain structure and the second source/drain structure have a higher doping concentration than the channel structure, and the third source/drain structure and the fourth source/drain structure have a higher doping concentration than the second channel structure.

5. The semiconductor device of claim 1, wherein the transistor structure further comprises:
a dielectric layer at least disposed around the sidewall of the second source/drain structure; and
a gate dielectric layer disposed around the sidewall of the channel structure and a sidewall of the dielectric layer.

6. The semiconductor device of claim 5, wherein the metal electrode is further disposed around a sidewall of the gate dielectric layer.

7. The semiconductor device of claim 5, wherein the gate dielectric layer has a high-k dielectric material.

8. The semiconductor device of claim 1, wherein the first source/drain structure further includes a second portion disposed below the portion and laterally extending beyond the sidewall of the portion.

9. The semiconductor device of claim 1, further comprising:
a second transistor structure vertically disposed with respect to the transistor structure and comprising:
a third source/drain structure;
a second channel structure disposed above the third source/drain structure;
a fourth source/drain structure disposed above the second channel structure, wherein a sidewall of a first portion of the third source/drain structure, a sidewall of the second channel structure, and a sidewall of the fourth source/drain structure are vertically aligned with one another; and
a second metal electrode disposed around the sidewall of the second channel structure and the sidewall of the fourth source/drain structure.

10. The semiconductor device of claim 9, wherein the first source/drain structure, the second source/drain structure, the third source/drain structure, and the fourth source/drain structure have a first conductive type, while the channel structure and second channel structure have a second, opposite conductive type.

11. A semiconductor device, comprising:
a transistor structure comprising:
a first source/drain structure having a first portion and a second portion, wherein the first portion is below the second portion and laterally extending beyond a sidewall of the second portion;
a channel structure disposed above the first source/drain structure and having a sidewall vertically aligned with the sidewall of the second portion of the first source/drain structure;
a second source/drain structure disposed above the channel structure and having a sidewall vertically aligned with the sidewall of the channel structure;
a dielectric layer disposed around the sidewall of the second source/drain structure;
a gate dielectric layer disposed around the sidewall of the channel structure and a sidewall of the dielectric layer; and
a metal electrode disposed around a sidewall of the gate dielectric layer.

12. The semiconductor device of claim 11, further comprising:
a second transistor structure comprising:
a third source/drain structure having a first portion and a second portion, wherein the first portion is below the second portion and laterally extending beyond a sidewall of the second portion;
a second channel structure disposed above the third source/drain structure and having a sidewall vertically aligned with the sidewall of the second portion of the third source/drain structure;
a fourth source/drain structure disposed above the second channel structure and having a sidewall vertically aligned with the sidewall of the second channel structure;
a second dielectric layer disposed around the sidewall of the fourth source/drain structure;
a second gate dielectric layer disposed around the sidewall of the second channel structure and a sidewall of the second dielectric layer; and
a second metal electrode disposed around a sidewall of the second gate dielectric layer.

13. The semiconductor device of claim 12, wherein the second transistor structure is laterally disposed next to the transistor structure.

14. The semiconductor device of claim 13, wherein the transistor structure and second transistor structure have opposite conductive types.

15. The semiconductor device of claim 12, wherein the second transistor structure is vertically disposed with respect to the transistor structure.

16. The semiconductor device of claim 15, wherein the transistor structure and second transistor structure have a same conductive type.

17. A method for manufacturing semiconductor devices, comprising:
forming a stack including a first semiconductor layer having a first conductive type, a second semiconductor layer having a second conductive type, and a third semiconductor layer having the first conductive type;
growing a dielectric layer along the first stack, with a first portion having a first thickness grown on the first and third semiconductor layers and a second portion having a second thickness grown on the second semiconductor layer, wherein the first thickness is greater than the second thickness;
forming a gate dielectric layer around a sidewall of the second semiconductor layer and a sidewall of the dielectric layer; and
forming a gate electrode around the gate dielectric layer.

18. The method of claim 17, concurrently with the step of forming the stack, further comprising:
forming a second stack laterally disposed next to the stack and including a fourth semiconductor layer having the second conductive type, a fifth semiconductor layer having the first conductive type, and a sixth semiconductor layer having the second conductive type.

19. The method of claim 18, concurrently with the step of forming the gate dielectric layer, further comprising:
growing a second dielectric layer along the second stack, with a first portion having the first thickness grown on the fourth and sixth semiconductor layers and a second portion having the second thickness grown on the fifth semiconductor layer.

20. The method of claim 17, wherein the first and third semiconductor layers have a first doping concentration and the second semiconductor layer has a second doping concentration, and wherein the first doping concentration is higher than the second doping concentration.
